(19) United States
(12) Patent Application Publication
(10) Pub. No.: US 2022/0254630 A1
(43) Pub. Date: Aug. 11, 2022

(54) LIQUID PHASE CONFORMAL SILICON OXIDE SPIN-ON DEPOSITION

(71) Applicant: Tokyo Electron Limited, Tokyo (JP)

(72) Inventor: Robert D. Clark, Livermore, CA (US)

(21) Appl. No.: 17/591,902

(22) Filed: Feb. 3, 2022

Related U.S. Application Data
(60) Provisional application No. 63/147,028, filed on Feb. 8, 2021.

(51) Int. Cl. H01L 21/02

(52) U.S. Cl. CPC H01L 21/02282; H01L 21/02164

(57) ABSTRACT

A method for liquid phase conformal silicon oxide spin-on deposition includes providing a substrate in a process chamber, spinning on the substrate a first reactant containing aluminum in a first liquid to form a self-limiting layer of the first reactant on the substrate, spinning on the substrate a second reactant containing a silanol reagent in a second liquid, where the self-limiting layer of the first reactant catalyzes adsorption of the silanol reagent on the substrate, and heat-treating the substrate to form a silicon oxide film from the adsorbed silanol reagent.

### CROSS REFERENCE TO RELATED PATENTS AND APPLICATIONS

This application claims priority to and the benefit of the filing date of U.S. Provisional Patent Application No. 63/147,028, filed Feb. 8, 2021, which application is incorporated herein by reference in its entirety.

### FIELD OF THE INVENTION

The present invention generally relates to a method of depositing a conformal oxide on a substrate for a semiconductor device, and more particularly to a method of depositing a silicon oxide film on a substrate by conformal liquid phase spin-on deposition.

### BACKGROUND OF THE INVENTION

The use of multi-patterning and self-aligned patterning schemes is ubiquitous in the semiconductor industry. Oxide layers are frequently used in patterning processes as sidewall spacers and the need for high throughput, low-cost, conformal oxide layers is continuing to grow.

### SUMMARY OF THE INVENTION

Embodiments of the invention describe a processing system and a method for liquid phase conformal silicon oxide spin-on deposition. According to one embodiment, the method includes providing a substrate in a process chamber, spinning on the substrate a first reactant containing aluminum in a first liquid to form a self-limiting layer of the first reactant on the substrate, spinning on the substrate a second reactant containing a silanol reagent in a second liquid, where the self-limiting layer of the first reactant catalyzes adsorption of the second reactant on the substrate, and heat-treating the substrate to form a silicon oxide film from the adsorbed silanol reagent.

### BRIEF DESCRIPTION OF THE DRAWINGS

In the drawings:

FIG. 1 is a process flow diagram for processing a substrate according to an embodiment of the invention;

FIGS. 2A-2F schematically show through cross-sectional views a method of forming a sidewall spacer on a raised feature according to an embodiment of the invention; and

FIG. 3 schematically shows a processing system for processing a substrate according to an embodiment of the invention.

DETAILED DESCRIPTION OF SEVERAL EMBODIMENTS

Embodiments of the invention provide a processing system and method for liquid phase conformal silicon oxide spin-on deposition.

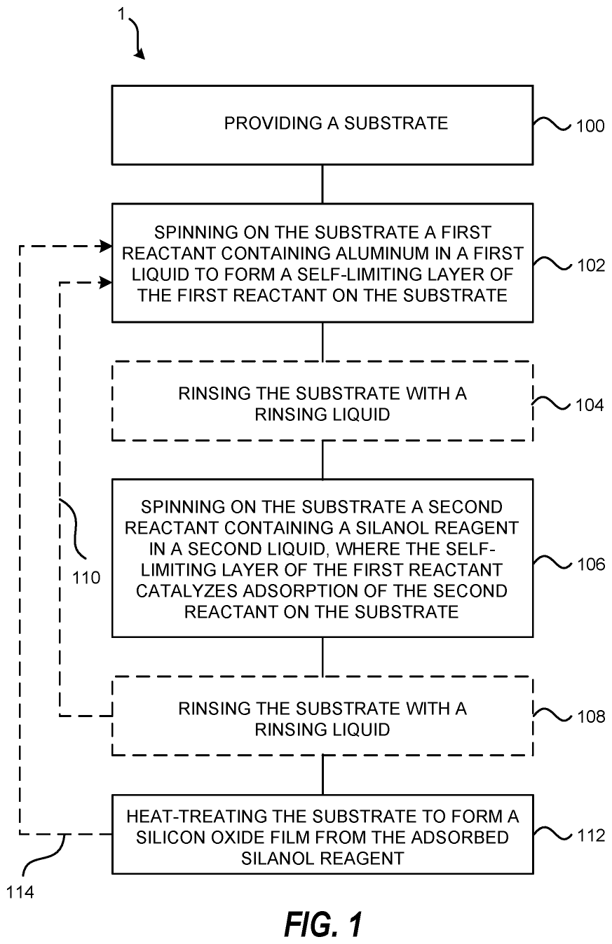

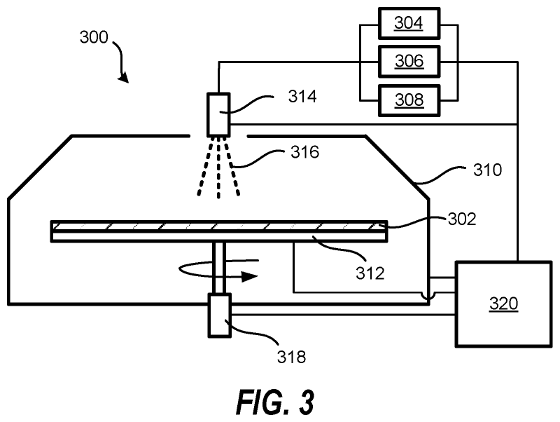

FIG. 1 is a process flow diagram 1 for processing a substrate according to an embodiment of the invention. In step 100, the method includes providing a substrate in a process chamber of a processing system. An exemplary processing system is schematically shown in FIG. 3. The processing system may be configured to process 200 mm substrates, 300 mm substrates, or larger-sized substrates. In fact, it is contemplated that the processing system may be configured to process substrates, wafers, or LCDs regardless of their size, as would be appreciated by those skilled in the art. Therefore, while aspects of embodiments of the invention will be described in connection with the processing of a semiconductor substrate, the invention is not limited solely thereto.

In step 102, the method includes spinning on the substrate a first reactant containing aluminum in a first liquid. The first reactant containing aluminum can, for example, include an aluminum salt, a metalorganic aluminum compound lacking direct aluminum-carbon bonds, or an organometallic aluminum compound containing direct aluminum-carbon bonds. Examples of aluminum salts include aluminum sulfate (Al₂(SO₄)₃), aluminum bromide (AlBr₃), aluminum chloride (AlCl₃), aluminum iodide (AlI₃), and aluminum hydroxide hydrate (Al(OH)₃×H₂O). Examples of a metalorganic aluminum compounds include aluminum β-diketonates, aluminum aikoxides, aluminum dialkylamides, and aluminum phosphine complexes Examples of aluminum β-diketonates include aluminum tris(acetylacetonate) (Al(acac)₃) and aluminum tris(hexafluoracetylacetonate (Al(hfac)₃). Examples of aluminum alkoxides include aluminum isopropoxide (Al(O-i-Pr)₃, where i-Pr is the isopropyl group, and aluminum tert-butoxide (Al(O-t-Bu)₃, where t-Bu is the tert-butoxide group. Examples of aluminum dialkylamides include tris(dimethylamino) aluminum ((Me₂N)₃Al) and tris(diethylamino) aluminum ((Et₂N)₃Al). One example of an aluminum phosphine complex includes aluminum phosphide (AlP). Examples of organometallic aluminum compounds include trimethylaluminum ((Al₂Me₆)) and triethylaluminum (Al₂Et₆).

The first liquid can include an organic compound that readily dissolves the first reactant and facilitates transport of the first reactant to the substrate in the process chamber. Non-limiting examples of the first liquid include octane and pyridine. Step 102 may be performed using a liquid delivery nozzle positioned above an upper surface of the rotating substrate. Upon coming in contact with the substrate, a self-limited layer of the first reactant or reaction products of the first reactants is formed on the substrate, and excess first reactant in the first liquid is spun off the substrate.

In step 104, the substrate is optionally rinsed with a rinsing liquid. The substrate may be spinning during the rinsing and the rinsing can aid in removing excess first reactant and reaction by-products from the substrate. Non-limiting examples of the rinsing liquid include octane, iso-octane, pyridine, toluene, a glycol, a ketone, an ether, an alcohol, or a xylene.

In step 106, the method includes spinning on the substrate a second reactant containing a silanol reagent in a second liquid, where the self-limiting layer of the first reactant containing aluminum catalyzes adsorption of the silanol reagent on the substrate. The second reactant containing the silanol reagent can include an alkoxysilanol, for example tris(tert-butoxy)silanol, tris(tert-pentoxy)silanol, methyl-bis(tert-butoxy)silanol, or methyl-bis(tert-pentoxy)silanol.

The first liquid can include an organic compound that readily dissolves the second reactant and facilitates transport of the second reactant to the substrate in the process chamber. Non-limiting examples of the second liquid include octane and pyridine. Step 106 may be performed using a liquid delivery nozzle positioned above an upper surface of the rotating substrate. Upon coming in contact with the substrate, a layer of the second reactant or reaction products of the second reactants is formed on the substrate, and excess first reactant in the second liquid is spun off the substrate.

In one example, a first reactant containing trimethyl aluminum (TMA) is spun onto a substrate containing Si—OH surface species, and thereafter a second reactant containing tris(tert-pentoxy)silanol (TPSOL) is spun onto the substrate where it reacts with the adsorbed Al-containing catalyst to form SiOH surface species by β-H elimination of C₅H₁₀. The adsorbed Al-containing catalyst is capable of reacting with a plurality of TPSOL molecules before the Al-containing catalyst is sequestered and the catalytic activity stops. Thereafter, no more TPSOL is added to the substrate.

In step 108, the substrate is optionally rinsed with a rinsing liquid. The substrate may be spinning during the rinsing and the rinsing can aid in removing excess second reactant and reaction by-products from the substrate. Non-limiting examples of the rinsing liquid include octane and pyridine.

The sequence of steps 102-108 may be repeated at least once to increase the surface coverage of the first reactant and the second reactant on the substrate. This is schematically shown by the process arrow 110. According to one embodiment, the one or more of the spinning on the substrate the first reactant, the spinning on the substrate the second reactant, and the heat treating are performed under an inert atmosphere that is substantially free of moisture.

In step 112, the substrate is heat-treated to form a silicon oxide film from the adsorbed silanol reagent or partially reacted silanol reagent. The heat-treating may be performed by increasing the substrate temperature above the temperature of steps 102-108 and carried out at a substrate temperature that is sufficiently high for desorbing any remailing liquid from the substrate and reacting the adsorbed silanol reagent to form the silicon oxide film. In some examples, the heat-treating can include baking the substrate at a temperature between about 80° C. and about 200° C., or between about 100° C. and about 150° C. The chemical composition of the resulting silicon oxide film can contain SiOₓ, where x is equal to or less than 2.

The sequence of steps 102-112 may be repeated at least once to increase a thickness of the silicon oxide film. This is schematically shown by the process arrow 114.

According to one embodiment, the substrate contains different first and second exposed material surfaces, and spinning on the substrate a first reactant containing aluminum in a first liquid selectively forms a self-limiting layer of the first reactant on the first exposed material surface but not on the second exposed material surface. Thereafter, the spinning on the substrate of a second reactant containing a silanol reagent in a second liquid, the self-limiting layer of the first reactant catalyzes selective adsorption of the silanol reagent on the first exposed surface but not on the second exposed surface. The following heat-treating step selectively forms a high quality, low-contaminant, silicon oxide film only on the first exposed surface.

In some examples, the first exposed material surface can include a dielectric material surface, for example SiO₂, a high-k material, or a low-k material. For example, the high-k material can include a metal oxide, for example Al₂O₃ or HfO₂. For example, the low-k material can include a SiCOH material. In one example, the second exposed material surface can include a metal surface, for example Cu, Ru, Co, or W. According to one embodiment, the substrate contains patterned features and the silicon oxide film is conformally deposited over the patterned features with at least substantially constant thickness. The patterned features can, for example, include recessed features, raised features, and a combination thereof

Using a spin-on process, high wafer (substrate) throughput is achievable in a semiconductor manufacturing setting and thus cost of ownership is decreased compared to conventional vapor phase deposition due to the inherent speed of the spin-on process. In addition, when using a spin-on process, the reaction can go through multiple cycles without moving the substrate from one bath to another and without handling the wafer, which decreases the potential for substrate contamination using the spin-on process. Further, the use of reactants and liquids that dry completely upon application or heat-treating without leaving behind water provides a way to increase throughput of the process and ensure that the reaction proceeds in a self-limited manner. In some examples, the spin-on process may be performed on track-based platforms that are conventionally used for photoresist spin-on and heat-treating (baking), and important applications in semiconductor manufacturing can include self-aligned multiple patterning schemes.

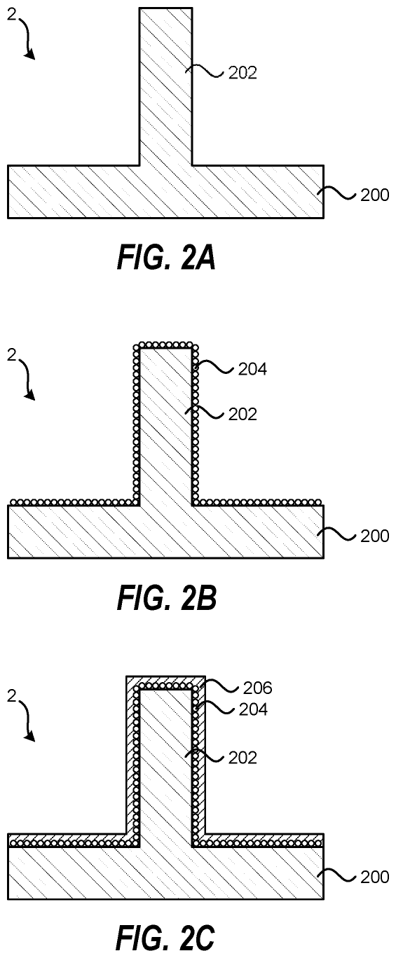

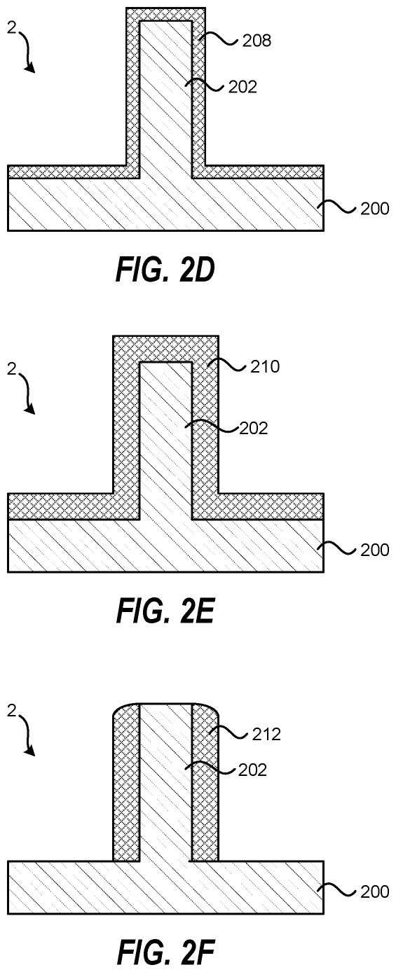

FIGS. 2A-2F schematically show through cross-sectional views a method of forming a sidewall spacer on a raised feature according to an embodiment of the invention. FIG. 2A shows a patterned substrate 2 containing a raised feature 202 and a base region 200. In some examples, a width of the raised feature 202 can be between about 5 nm and about 200 nm, between about 5 nm and about 50 nm, between about 5 nm and about 20 nm, between about 10 nm and about 100 nm, or between about 10 nm and about 50 nm. In some examples, a height of the raised feature 202 can be between about 10 nm and about 500 nm, between about 20 nm and about 200 nm, between about 20 nm and about 100 nm, between about 50 nm and about 500 nm, or between about 50 nm and about 200 nm.

FIG. 2B shows the patterned substrate 2 after spinning on a first reactant containing aluminum in a first liquid. Upon coming in contact with the patterned substrate 2, a self-limited layer 204 of the first reactant or reaction products of the first reactants is formed on the substrate 2, and excess first reactant in the first liquid is spun off the substrate. Thereafter, the patterned substrate 2 is optionally rinsed with a rinsing liquid. The substrate may be spinning during the rinsing and the rinsing can aid in removing excess first reactant and reaction by-products from the patterned substrate 2. The self-limited nature of the adsorption of the first reactant, in some cases near-perfect, results in very high conformality over relatively high aspect ratio structures even at very small nanometer scale dimensions. This allows for excellent thickness control and extremely low non-uniformity across large substrate areas.

FIG. 2C shows the patterned substrate 2 after spinning on a second reactant containing a silanol reagent in a second liquid. Upon coming in contact with the substrate, a conformal layer 206 of the second reactant or reaction products of the second reactant is formed on the patterned substrate 2, and excess first reactant in the second liquid is spun off the patterned substrate 2.

FIG. 2D shows the patterned substrate 2 following a heat-treatment that forms a silicon oxide film from the adsorbed silanol reagent and reaction products thereof. The heat-treating may be performed by increasing the substrate temperature above the temperature of the spin-on and rinsing steps and may be carried out at a substrate temperature that is sufficiently high for desorbing any remailing liquid from the substrate and fully reacting the adsorbed silanol reagent to form the silicon oxide film. In some examples, the heat-treating can include baking the substrate at a temperature between about 80° C. and about 200° C., or between about 100° C. and about 150° C.

FIG. 2E shows the patterned substrate 2 following repeating the steps of spinning, rinsing, and heat-treating to form a thick silicon oxide film 210.

FIG. 2F shows the patterned substrate 2 following an anisotropic dry etching process that forms a sidewall spacer 212 on the sidewall of the raised feature 202.

FIG. 3 schematically shows a processing system 300 for processing a substrate according to an embodiment of the invention. The processing system 300 may be a semi-closed spin-on deposition system similar to what the semiconductor industry currently employs for coating substrates (wafers) with photoresist layers. The semi-closed configuration allows fume control and minimizes exhaust volume. The processing system 300 contains a process chamber 310 that includes a substrate holder 312 for supporting, heating, and rotating (spinning) a substrate 302, a rotating means 318 (e.g., a motor), and a liquid delivery nozzle 314 configured for providing a processing liquid 316 to an upper surface of the substrate 302. Liquid supply systems 304, 306 and 308 supply different processing liquids to the liquid delivery nozzle 314. The different processing liquids can, for example, include a first reactant containing aluminum in a first liquid, a second reactant containing a silanol reactant in a second liquid, and a rinsing liquid. According to other embodiments, the processing system 300 may include additional liquid delivery nozzles (not shown) for providing the different liquids to the substrate. Exemplary rotating speeds can be between about 500 rpm and about 1500 rpm, for example 1000 rpm, during exposure of the upper surface of the substrate 302 to the processing liquid 316.

The processing system 300 further includes a controller 320 that can be coupled to and control the process chamber 310, the liquid supply systems 304, 306 and 308, the liquid delivery nozzle 314, the rotating means 318, and means for heating the substrate holder 312. The substrate 302 may be under an inert atmosphere during the film deposition. The processing system 300 may be configured to process 200 mm substrates, 300 mm substrates, or larger-sized substrates. The processing system 300 may be configured to process substrates, wafers, or LCDs regardless of their size, as would be appreciated by those skilled in the art. Therefore, while aspects of the invention will be described in connection with the processing of a semiconductor substrate, the invention is not limited solely thereto.

The processing system 300 may be configured for heat-treating the substrate 302 by heating the substrate holder 312. Alternatively, the substrate 302 may be transferred to a second processing system (not shown) for heat-treating.

A processing system and method for liquid phase conformal silicon oxide spin-on deposition have been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A substrate processing method comprising:
providing a substrate in a process chamber;
spinning on the substrate a first reactant containing aluminum in a first liquid to form a self-limiting layer of the first reactant on the substrate;
spinning on the substrate a second reactant containing a silanol reagent in a second liquid, wherein the self-limiting layer of the first reactant catalyzes adsorption of the silanol reagent on the substrate; and
heat-treating the substrate to form a silicon oxide film from the adsorbed silanol reagent.

2. The method of claim 1, further comprising:
sequentially repeating the spinning steps at least once to increase the surface saturation of the first and second reactants.

3. The method of claim 1, further comprising:
sequentially repeating the spinning steps and the heat-treating at least once to increase a thickness of the silicon oxide film on the substrate.

4. The method of claim 1, further comprising
rinsing the substrate with a rinsing liquid after one or more of the spinning steps, after the heat-treating, or both.

5. The method of claim 4, wherein the rinsing liquid contains octane, iso-octane, pyridine, toluene, a glycol, a ketone, an ether, an alcohol, or a xylene.

6. The method of claim 1, wherein the substrate contains different first and second exposed material surfaces, and the silicon oxide film is selectively formed on the first exposed surface but not on the second exposed material surface.

7. The method of claim 1, wherein the first exposed material surface includes a dielectric material surface and the second exposed material surface includes a metal surface.

8. The method of claim 1, wherein the substrate contains a raised feature and the silicon oxide film is conformally formed on surfaces of the raised feature.

9. The method of claim 1, wherein the first reactant containing aluminum includes an aluminum salt, an aluminum alkoxide, a metalorganic aluminum compound, or an organometallic aluminum compound.

10. The method of claim 1, wherein the second reactant containing a silanol reagent includes an alkoxysilanol.

11. The method of claim 10, wherein the alkoxysilanol includes tris(tert-butoxy)silanol, tris(tert-pentoxy)silanol, methyl-bis(tert-butoxy)silanol, or methyl-bis(tert-pentoxy)silanol.

12. The method of claim 1, wherein the heat-treating includes baking the substrate at a temperature between about 80° C. and about 200° C.

13. The method of claim 1, wherein the heat-treating includes baking the substrate at a temperature between about 100° C. and about 150° C.

14. The method of claim 1, wherein one or more of the spinning on the substrate the first reactant, the spinning on the substrate the second reactant, and the heat treating are performed under an inert atmosphere that is substantially free of moisture.

15. A substrate processing method comprising:
providing a substrate in a process chamber, wherein the substrate contains a raised feature;
spinning on the substrate a first reactant containing trimethyl aluminum in a first liquid to form a self-limiting layer of the first reactant on the substrate;
spinning on the substrate a second reactant containing a silanol reagent in a second liquid, wherein the self-limiting layer of the trimethyl aluminum catalyzes adsorption of the silanol reagent on the substrate; and
heat-treating the substrate to form a conformal silicon oxide film on surfaces of the raised feature from the adsorbed silanol reagent.

16. The method of claim 15, wherein the alkoxysilanol includes tris(tert-butoxy)silanol, tris(tert-pentoxy)silanol, methyl-bis(tert-butoxy)silanol, or methyl-bis(tert-pentoxy)silanol.

17. The method of claim 15, wherein the heat-treating includes baking the substrate at a temperature between about 80° C. and about 200° C.

18. The method of claim 15, further comprising:
sequentially repeating at least once the spinning on the substrate the first reactant, the spinning on the substrate the second reactant, and the heat treating to increase a thickness of the silicon oxide film on the substrate.

19. A substrate processing method comprising:
providing a substrate in a process chamber, wherein the substrate contains different first and second exposed material surfaces;
spinning on the substrate a first reactant containing trimethyl aluminum in a first liquid to selectively form a self-limiting layer of the trimethyl aluminum on the first exposed surface on the substrate;
spinning on the substrate a second reactant containing a silanol reagent in a second liquid, wherein the self-limiting layer of the trimethyl aluminum catalyzes selective adsorption of the silanol reagent on the exposed first material surface; and
heat-treating the substrate to selectively form a conformal silicon oxide film on the exposed first material surface from the adsorbed silanol reagent.

20. The method of claim 19, wherein the alkoxysilanol includes tris(tert-butoxy)silanol, tris(tert-pentoxy)silanol, methyl-bis(tert-butoxy)silanol, or methyl-bis(tert-pentoxy)silanol.

21. The method of claim 19, further comprising:
sequentially repeating at least once the spinning on the substrate the first reactant, the spinning on the substrate the second reactant, and the heat treating to increase a thickness of the silicon oxide film on the exposed first material surface.
